(19) United States
(12) Patent Application Publication
(10) Pub. No.: US 2017/0288564 A1
(43) Pub. Date: Oct. 5, 2017

(54) POWER CONVERSION APPARATUS AND METHOD FOR MANUFACTURING THE SAME

(71) Applicant: Keihin Corporation, Tokyo (JP)

(72) Inventors: Takashi Ishii, Shioya-gun (JP); Shinya Saito, Kakuda-shi (JP)

(21) Appl. No.: 15/467,218

(22) Filed: Mar. 23, 2017

(30) Foreign Application Priority Data
Mar. 29, 2016 (JP) 2016-066409
Dec. 12, 2016 (JP) 2016-240317

(51) Int. Cl. H02M 7/00; H02M 7/537; H05K 1/18; H01L 21/48; H01L 23/373; H01L 23/495; H01L 23/00; H02P 27/06; H05K 3/34

(52) U.S. Cl. CPC H02M 7/003; H02P 27/06; H02M 7/537; H05K 1/181; H05K 3/341; H01L 23/3735; H01L 23/49541; H01L 24/32; H01L 24/83; H01L 21/4853; H01L 21/4825; H01L 23/49568; H05K 2201/10174; H05K 2201/10166; H01L 2924/1203; H01L 2924/13055; H01L 2224/83815; H01L 2224/32245; H01L 2924/1425; H01L 2924/37001

(57) ABSTRACT

A second lead frame is set onto a conductive layer and a busbar. The second lead frame has holes previously formed at opposite ends thereof, and pieces of solder material or solder pieces are inserted into the holes. Then, the solder pieces are vibrated by an ultrasonically vibrating tool, whereby the solder pieces are melted without having a high temperature. The second lead frame is thus bonded to the conductive layer and the busbar. A semiconductor element and the busbar are connected by a first lead frame and the second lead frame. The connection structure thereof is such that the second lead frame to be bonded by ultrasonic bonding or other bonding methods is not directly in contact with the semiconductor element, which eliminates the risk of damage to the semiconductor element.

### FIELD OF THE INVENTION

The present invention relates to a power conversion apparatus for converting DC power stored in a battery to AC power and supplying it to a motor, and a method for manufacturing the power conversion apparatus.

### BACKGROUND OF THE INVENTION

Inverter apparatuses mounted on hybrid vehicles and electric vehicles include thereinside a power module which performs DC/AC power conversion. The power module includes an IGBT (insulated gate bipolar transistor) as a switching element and a diode, and these semiconductor elements are electrically connected to a busbar via a wiring such as a bonding wire or a bonding tape. Various electrical connection structures are known as disclosed, for example, in Japanese Patent Application Laid-Open Publication (JP-A) No. 2012-151198 (FIGS. 1 and 3).

JP 2012-151198A shows in FIG. 1 bonding tapes (70) (hereinafter, reference numerals in parentheses are those used in JP 2012-151198M are laid to bridge over an IGBT (10), a diode (20) and a busbar (40), and ultrasonically bonded at one ends (70a) to the busbar (40), at intermediate parts (70b) to the diode (20), and at the other ends (70c) to the IGBT (10), as described in paragraph [0013] of JP 2012-151198A.

As shown in FIG. 3 of JP 2012-151198A, ultrasonic bonding is performed by pressing an ultrasonically vibrating tool (80) onto the bonding tape (70). However, in JP 2012-151198A, the bonding tapes (70) are bonded directly to the IGBT (10) and the diode (20), and therefore the IGBT (10) and the diode (20) might undergo damage or breakage due to vibration and pressure applied by the tool (80).

To improve manufacturing yield, damage to the semiconductor elements (i.e., the IGBT (10) and the diode (20)) must be avoided. Thus, an improved power conversion apparatus and a manufacturing method of the power conversion apparatus is required which allows an electrical connection in a power module to be performed without giving damage to the semiconductor elements.

### SUMMARY OF THE INVENTION

It is therefore an object of the present invention to provide a power conversion apparatus and a manufacturing method of the power conversion apparatus which allow an electrical connection in a power module to be performed without giving damage to the semiconductor elements.

According to a first aspect of the present invention, there is provided a power conversion apparatus comprising: an insulating substrate having a conductive layer formed on at least one side surface of an insulating plate; a semiconductor element mounted on the insulating substrate; a busbar arranged at a position apart from the semiconductor element by a predetermined length; and a conductive member for electrically connecting the busbar and the semiconductor element, wherein the conductive member is composed of a first connecting member which connects the semiconductor element and the conductive layer, and a second connecting member which connects the conductive layer and the busbar.

According to a second aspect of the present invention, there is provided a power conversion apparatus comprising: an insulating substrate having a conductive layer formed on at least one side surface of an insulating plate; a semiconductor element mounted on the insulating substrate; a busbar arranged at a position apart from the semiconductor element by a predetermined length; and a conductive member for electrically connecting the busbar and the semiconductor element, wherein the conductive member is composed of a first connecting member extending from the semiconductor element, and a second connecting member extending from the busbar to be connected directly to the first connecting member.

It is preferable that the semiconductor element is an integrated element formed by integrating a diode and an insulated gate bipolar transistor.

Preferably, a lead frame is used as the first connecting member.

Preferably, a ribbon wire is used as the second connecting member.

It is also preferable that a lead frame is used as the second connecting member.

According to a third aspect of the present invention, there is provided a manufacturing method of the power conversion apparatus, in which a lead frame is used as the first connecting member, and which comprises performing reflow soldering to connect the lead frame at one end to the semiconductor element and at the other end to the conductive layer or the second connecting member.

According to a fourth aspect of the present invention, there is provided a manufacturing method of the power conversion apparatus, in which a ribbon wire is used as the second connecting member, and which comprises performing ribbon bonding to connect the ribbon wire at one end to the conductive layer or the first connecting member and at the other end to the busbar.

According to a fifth aspect of the present invention, there is provided a manufacturing method of the power conversion apparatus, in which a lead frame is used as the second connecting member, and which comprises performing ultrasonic bonding to connect the lead frame at one end to the conductive layer or the first connecting member and at the other end to the busbar.

In the first aspect of the invention, the conductive member is composed of the first connecting member which connects the semiconductor element and the conductive layer on the insulating substrate, and the second connecting member which connects the conductive layer and the busbar. In other words, the conductive member is divided into two connecting members, whereby the connecting members can be connected separately on the conductive layer. With this configuration, even when the second connecting member is bonded by ultrasonic bonding, vibration generated therefrom does not affect the first connecting member which is separated from the second connecting member. Further, the first connecting member can be bonded by a bonding method which does not give damage to the semiconductor element. As a result, the power conversion apparatus is realized which allows the electrical connection in a power module to be performed without giving damage to the semiconductor elements.

In the second aspect of the invention, the conductive member is composed of the first connecting member extending from the semiconductor element, and the second connecting member extending from the busbar to be connected directly to the first connecting member. In other words, the conductive member is divided into two connecting members, and the second connecting member is connected directly to the first connecting member as a separate member. With this configuration, even when the second connecting member is bonded by ultrasonic bonding, vibration generated therefrom can be absorbed by the first connecting member, thereby preventing the semiconductor element from being damaged. Further, the first connecting member can be bonded by a bonding method which does not give damage to the semiconductor element. As a result, the power conversion apparatus is realized which allows the electrical connection in the power module to be performed without giving damage to the semiconductor elements.

In the invention, the semiconductor element is the integrated element formed by integrating the diode and the IGBT (insulated gate bipolar transistor). Using the integrated element allows the power conversion apparatus to be made comp act.

In the invention, the lead frame is used as the first connecting member. A layer or portion of solder material is put between one end of the lead frame and the semiconductor element, and a layer or portion of solder material is put between the other end of the lead frame and the conductive layer. Then, the assembly including the lead frame, the semiconductor element and the conductive layer is placed in an atmosphere having a temperature equal to or above the melting point of the solder material. In this manner, the lead frame can be bonded thereto.

In the invention, the ribbon wire is used as the second connecting member. The conductive layer and the busbar can be connected via the ribbon wire by ribbon bonding.

In the invention, the lead frame is used as the second connecting member. The lead frame can be bonded by ultrasonic bonding to the conductive layers and the busbar.

In the third aspect of the invention, the lead frame is used as the first connecting member, and the lead frame is bonded by reflow soldering at the one end to the semiconductor element and at the other end to the conductive layer or the second connecting member. Reflow soldering is a bonding method in which a layer or portion of solder material is put between parts to be bonded, for example, between the insulating substrate and the semiconductor element, the assembly including the parts is then gradually heated to a temperature equal to or above the melting point of the solder material, and is cooled thereafter, whereby the bonding operation of the parts is completed. The solder material used herein melts at a temperature lower than a tolerable temperature of the semiconductor element. The bonding operation can be performed without applying vibration and pressure, the semiconductor element is free from the risk of damage.

In a case where a ribbon wire is used as the first connecting member, two or more ribbon wires are required to be connected. In the invention, however, the single lead frame is used, thereby enabling the number of components and man-hours to be reduced. Further, the connection strength can be higher than in the case where the ribbon wire is used. Additionally, a heat of the semiconductor element can be transmitted via the lead frame to the insulating substrate, which enables improved heat dissipation.

In the fourth aspect of the invention, the ribbon wire is used as the second connecting member, and the ribbon wire is bonded by ribbon bonding. Since the second connecting member is separated from the semiconductor element, the bonding method can be selected freely. Further, the ribbon wire having excellent flexibility can flexibly cope with a height difference.

In the fifth aspect of the invention, the lead frame is used as the second connecting member, and the lead frame is bonded by ultrasonic bonding. Since the second connecting member is separated from the semiconductor element, as noted above, the bonding method can be selected freely. In ultrasonic bonding, the solder material is melted by ultrasonic vibration without being heated. Since high temperature heating is not performed, an inexpensive resin material can be used as a support member (i.e., power module case) for the busbar. Further, a flux is not necessary in ultrasonic bonding. A process of cleaning flux residue is therefore unnecessary, which enables the number of processes and man-hours to be reduced.

### BRIEF DESCRIPTION OF THE DRAWINGS

FIG. 1(a) is an exploded perspective view of a power conversion apparatus according to the present invention;

FIG. 1(b) is a plan view of a power module case;

FIGS. 2(a) and 2(b) are enlarged partial views illustrating essential parts of the power module case;

FIGS. 3(a) to 3(e) illustrate a manufacturing method of the power conversion apparatus according to the present invention; and

FIGS. 4(a) to 4(e) illustrate another manufacturing method of the power conversion apparatus according to the present invention.

### DETAILED DESCRIPTION OF THE PREFERRED EMBODIMENTS

Certain preferred embodiments of the present invention will be described in detail below, by way of example only, with reference to the accompanying drawings.

A power conversion apparatus 10 according to the present invention is disposed between a battery and a motor. The battery and the motor are well known in the art, and illustrations thereof will be omitted. The motor is used herein as a generator, and generated power is stored in the battery. Thus, the power conversion apparatus 10 according to the present invention is disposed between the battery and the motor, or the battery and the generator.

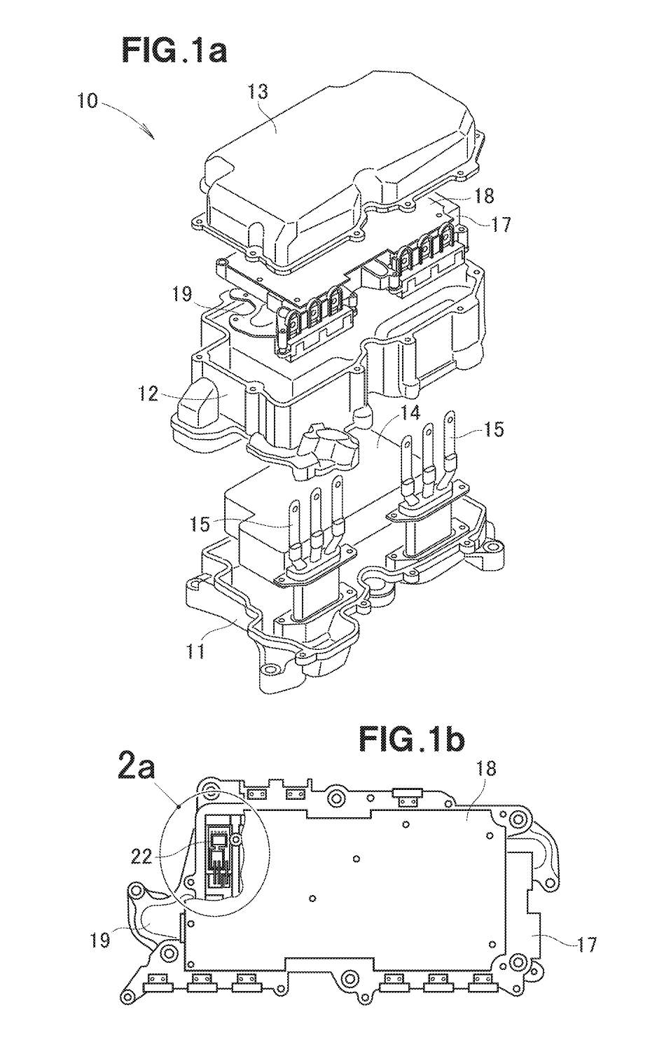

As shown in FIG. 1(a), a power conversion apparatus 10 has a body constituted of a lower case 11, a middle case 12, and an upper cover 13, and includes therewithin a condenser 14, motor-side busbars 15 formed for connection to the motor, and a power module case 17 accommodating a power module.

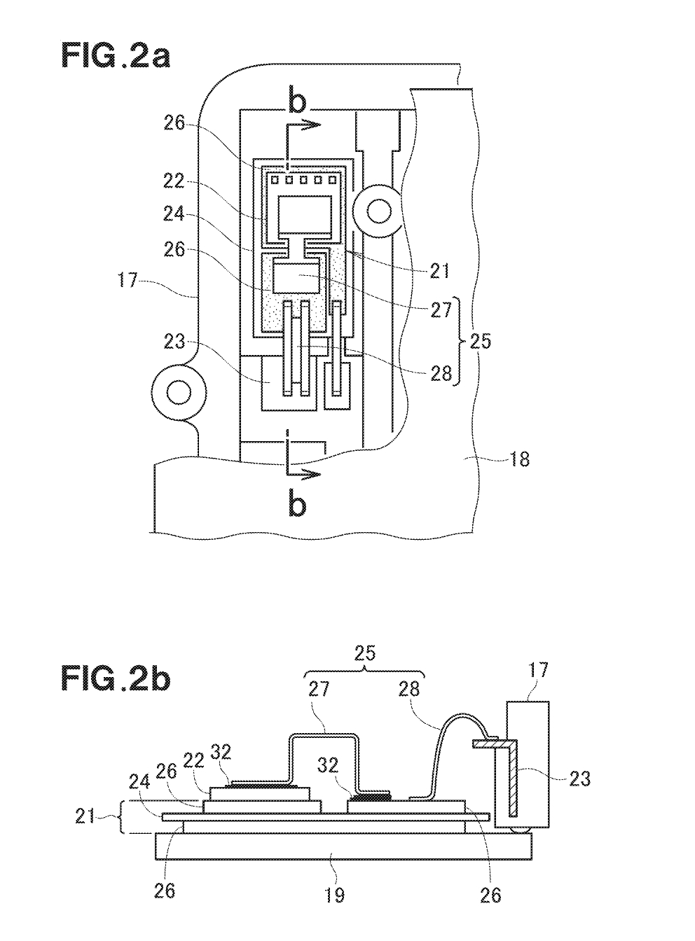

As shown in FIG. 1(b), the power module case 17 includes a circuit substrate 18 arranged on an upper surface thereof for controlling the power module, a cooler 19 arranged on a lower surface thereof for cooling the power module, and a semiconductor element 22 arranged thereinside. The semiconductor element 22 and the like can be mounted on an insulating substrate (21, shown in FIG. 2), and the insulating substrate may be in contact with or joined with an upper surface of the cooler 19. In this case, the semiconductor element 22 and the like are surrounded by the power module case 17.

FIG. 2(a) is an enlarged view of section 2(a) of FIG. 1(b), and FIG. 2(b) is a cross-sectional view taken along line b-b of FIG. 2(a). As shown in FIG. 2(b), the semiconductor element 22 is mounted on the insulating substrate 21. As the insulating substrate 21, a DCB (Direct Copper Bond) substrate composed of a ceramic plate 24 and copper layers 26 bonded directly to the ceramic plate 24 is particularly suitable, however, a general-purpose copper foil substrate may be used. In FIG. 2(b), the copper layer 26 on the side on which the semiconductor element 22 is mounted is divided into two portions. The copper layers 26 are conductive layers, and thus hereinafter referred to as conductive layers 26.

Although the semiconductor element 22 can include a diode and an IGBT (insulated gate bipolar transistor), an integrated element formed by integrating the diode and the IGBT is particularly suitable. Using the integrated element allows the power conversion apparatus 10 to be made comp act.

Further, a case-side busbar 23 is embedded in the power module case 17. Conductive members 25 which electrically connect the semiconductor element 22 and the busbar 23 include a first connecting member 27 which connects the semiconductor element 22 and the conductive layer 26 on the insulating substrate 21, and a second connecting member 28 which connects the conductive layer 26 and the busbar 23. A layout in plan view is shown in FIG. 2(a) with the same reference numerals as those used in FIG. 2(b), and a detailed description thereof is omitted.

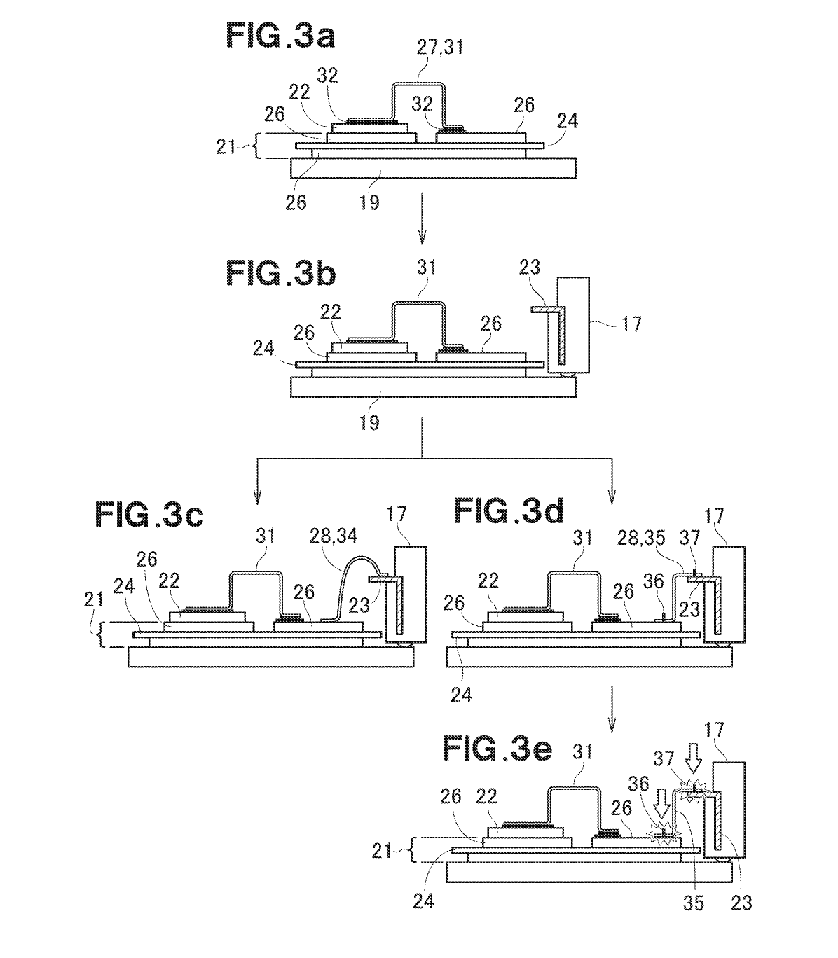

The following is a description of a manufacturing method mainly including a connecting method. In FIG. 3(a), reflow soldering is performed. More specifically, a first lead frame 31 as the first connecting member 27 is set onto the semiconductor element 22 and the conductive layer 26. At this time, a layer or portion of solder material 32 is put between one end of the first lead frame 31 and the semiconductor element 22, and a layer or portion of solder material 32 is put between the other end of the first lead frame 31 and the conductive layer 26. Then, the assembly including the first lead frame 31, the semiconductor element 22 and the conductive layer 26 is placed in an atmosphere having a temperature equal to or above the melting point of the solder material 32. The solder material 32 is melted, and the assembly is thereafter cooled. Connection of the first lead frame 31 is thus completed.

Although a ribbon wire may be used as the first connecting member 27, in that case, two or more ribbon wires are required to be connected. Using the single first lead frame 31 enables the number of components and man-hours to be reduced. Further, in the case where the first lead frame 31 is used, the connection strength can be higher than in the case where the ribbon wire is used. Additionally, a heat of the semiconductor element 22 can be transmitted to the cooler 19 via the first lead frame 31 and the conductive layer 26, which enables improved heat dissipation.

Next, as shown in FIG. 3(b), the power module case 17 having the busbar 23 is attached. As the second connecting member 28, both of a ribbon wire 34 and a second lead frame 35 can be adopted.

In a case where the ribbon wire 34 is used as the second connecting member 28, as shown in FIG. 3(c), the conductive layer 26 and the busbar 23 are connected by the ribbon wire 34. Herein, ribbon bonding is performed. More specifically, first, one end of the ribbon wire 34 is bonded to the conductive layer 26 by means of an ultrasonically vibrating tool. The ribbon wire 34 is then bent in an S-shape by a tool. Then, the other end of the ribbon wire 34 is bonded to the busbar 23 by the ultrasonically vibrating tool. These steps may be performed in reverse order, that is, the ribbon wire 34 may be first bonded to the busbar 23, then bent, and bonded to the conductive layer 26.

In ribbon bonding, vibration and pressure are inevitably applied to bonding parts. However, herein, the ribbon wire 34 is not directly bonded to the semiconductor element 22, so that the vibration and the pressure does not affect the semiconductor element 22. Thus, damage to the semiconductor element 22 can be avoided. Additionally, in ribbon bonding, a height difference between the conductive layer 26 and the busbar 23 causes no problem. Further, the ribbon wire 34 may be bonded directly to the first lead frame 31 at the bonding part with the conductive layer 26. In this structure, the first lead frame 31 and the ribbon wire 34 are overlaid with each other to be bonded, so that required bonding area on the conductive layer 26 can be reduced, thereby allowing the power conversion apparatus to be made compact.

In a case where the second lead frame 35 is used as the second connecting member 28, as shown in FIG. 3(d), the second lead frame 35 is set onto the conductive layer 26 and the busbar 23. The second lead frame 35 has holes previously formed at opposite ends thereof, and pieces of solder material or solder pieces 36, 37 are inserted into the holes.

Then, as shown in FIG. 3(e), the second lead frame 35 is bonded to the conductive layer 26 and the busbar 23. The bonding operation is performed preferably by ultrasonic bonding. More specifically, the solder piece 36 is vibrated by the ultrasonically vibrating tool, and the solder piece 36 is thereby melted without having a high temperature. The solder piece 37 is then vibrated by the ultrasonically vibrating tool, and the solder piece 37 is thereby melted without having a high temperature. The bonding operation of the second lead frame 35 is thus completed. The steps may be performed in reverse order, that is, the second lead frame 35 may be first bonded to the busbar 23 and then to the conductive layer 26. Further, the second lead frame 35 may be bonded directly to the first lead frame 31 at the bonding part with the conductive layer 26. In this structure, the first lead frame 31 and the second lead frame 35 are overlaid with each other to be bonded, so that required bonding area on the conductive layer 26 can be reduced, thereby allowing the power conversion apparatus to be made compact.

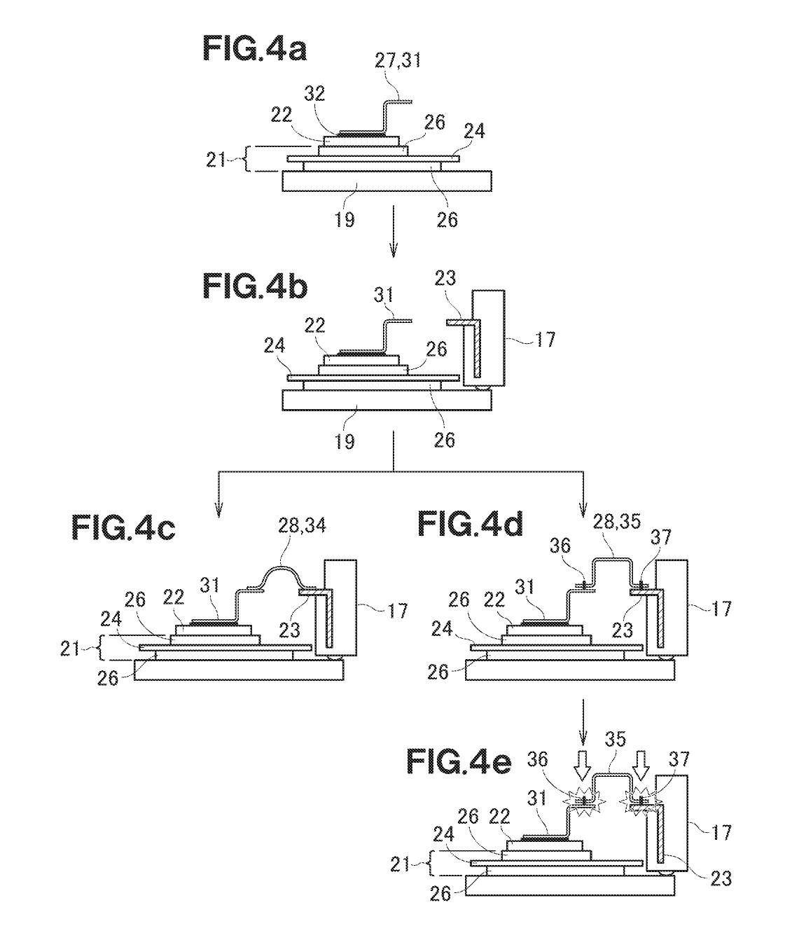

Below will be described a modified embodiment of the present invention. In FIG. 4(a), reflow soldering is performed. More specifically, a first lead frame 31 as the first connecting member 27 is set onto the semiconductor element 22. At this time, a layer or portion of solder material 32 is put between one end of the first lead frame 31 and the semiconductor element 22. Then, the assembly including the first lead frame 31 and the semiconductor element 22 is placed in an atmosphere having a temperature equal to or above the melting point of the solder material 32. The solder material 32 is melted, and the assembly is thereafter cooled. Connection of the first lead frame 31 is thus completed.

Next, as shown in FIG. 4(b), a power module case 17 having a busbar 23 is attached. Both of a ribbon wire 34 and a second lead frame 35 can be adopted as the second connecting member 28.

In a case where the ribbon wire 34 is used as the second connecting member 28, as shown in FIG. 4(c), the first lead frame 31 and the busbar 23 are connected by the ribbon wire 34. Herein, ribbon bonding is performed. More specifically, first, one end of the ribbon wire 34 is bonded to the first lead frame 31 by means of the ultrasonically vibrating tool. The ribbon wire 34 is then bent in an S-shape by a tool. Then, the other end of the ribbon wire 34 is bonded to the busbar 23 by the ultrasonically vibrating tool. These steps may be performed in reverse order, that is, the ribbon wire 34 may be first bonded to the busbar 23, then bent, and bonded to the first lead frame 31.

In a case where the second lead frame 35 is used as the second connecting member 28, as shown in FIG. 4(d), the second lead frame 35 is set onto the first lead frame 31 and the busbar 23. The second lead frame 35 has holes previously formed at opposite ends thereof, and pieces of solder material or solder pieces 36, 37 are inserted into the holes.

Then, as shown in FIG. 4(e), the second lead frame 35 is bonded to the first lead frame 31 and the busbar 23. The bonding operation is performed preferably by ultrasonic bonding. More specifically, the solder piece 36 is vibrated by the ultrasonically vibrating tool, and the solder piece 36 is thereby melted without having a high temperature. The solder piece 37 is then vibrated by the ultrasonically vibrating tool, and the solder piece 37 is thereby melted without having a high temperature. The bonding operation of the second lead frame 35 is thus completed. The steps may be performed in reverse order, that is, the second lead frame 35 may be first bonded to the busbar 23 and then to the first lead frame 31.

In FIGS. 4(c) and 4(e), ultrasonic vibration is transmitted to the semiconductor element 22 via the first lead frame 31. However, since the first lead frame 31 is a thin belt-like sheet and exhibits a vibration attenuating function by its shape, effect of the vibration on the semiconductor element 22 is negligible. Further, the solder material 32 put between the first lead frame 31 and the semiconductor element 22 also exhibits the vibration attenuating function.

According to the present invention, as described above, the semiconductor element 22 and the busbar 23 are connected by the first lead frame 31 and the second lead frame 35. The connection structure thereof is such that the second lead frame 35 to be bonded by ultrasonic bonding or other bonding methods is not directly in contact with the semiconductor element 22, which eliminates the risk of damage to the semiconductor element 22.

Note that the shapes of the first lead frame 31 and the second lead frame 35 are arbitrary. Further, the power conversion apparatus 10 can not only be mounted on electric vehicles and so-called hybrid vehicles, but also be applied to ships and for general industrial use.

The present invention is suitably used for power conversion apparatuses mounted on vehicles.

Obviously, various minor changes and modifications of the present invention are possible in light of the above teaching. It is therefore to be understood that within the scope of the appended claims the invention may be practiced otherwise than as specifically described.

1. A power conversion apparatus comprising:
an insulating substrate having a conductive layer formed on at least one side surface of an insulating plate;
a semiconductor element mounted on the insulating substrate;
a busbar arranged at a position apart from the semiconductor element by a predetermined length; and
a conductive member for electrically connecting the busbar and the semiconductor element,
wherein the conductive member is composed of a first connecting member which connects the semiconductor element and the conductive layer, and a second connecting member which connects the conductive layer and the busbar.

2. The power conversion apparatus according to claim 1, wherein the semiconductor element is an integrated element formed by integrating a diode and an insulated gate bipolar transistor.

3. The power conversion apparatus according to claim 1, wherein a lead frame is used as the first connecting member.

4. The power conversion apparatus according to claim 1, wherein a ribbon wire is used as the second connecting member.

5. The power conversion apparatus according claim 1, wherein a lead frame is used as the second connecting member.

6. A power conversion apparatus comprising:
an insulating substrate having a conductive layer formed on at least one side surface of an insulating plate;
a semiconductor element mounted on the insulating substrate;
a busbar arranged at a position apart from the semiconductor element by a predetermined length; and
a conductive member for electrically connecting the busbar and the semiconductor element,
wherein the conductive member is composed of a first connecting member extending from the semiconductor element, and a second connecting member extending from the busbar to be connected directly to the first connecting member.

7. The power conversion apparatus according to claim 6, wherein the semiconductor element is an integrated element formed by integrating a diode and an insulated gate bipolar transistor.

8. The power conversion apparatus according to claim 6, wherein a lead frame is used as the first connecting member.

9. The power conversion apparatus according to claim 6, wherein a ribbon wire is used as the second connecting member.

10. The power conversion apparatus according to claim 6, wherein a lead frame is used as the second connecting member.

11. A manufacturing method of the power conversion apparatus according to claim 1, in which a lead frame is used as the first connecting member, and which comprises performing reflow soldering to connect the lead frame at one end to the semiconductor element and at the other end to the conductive layer or the second connecting member.

12. A manufacturing method of the power conversion apparatus according to claim 1, in which a ribbon wire is used as the second connecting member, and which comprises performing ribbon bonding to connect the ribbon wire at one end to the conductive layer or the first connecting member and at the other end to the busbar.

13. A manufacturing method of the power conversion apparatus according to claim 1, in which a lead frame is used as the second connecting member, and which comprises performing ultrasonic bonding to connect the lead frame at one end to the conductive layer or the first connecting member and at the other end to the busbar.

14. A manufacturing method of the power conversion apparatus according to claim 6, in which a lead frame is used as the first connecting member, and which comprises performing reflow soldering to connect the lead frame at one end to the semiconductor element and at the other end to the conductive layer or the second connecting member.

15. A manufacturing method of the power conversion apparatus according to claim 6, in which a ribbon wire is used as the second connecting member, and which comprises performing ribbon bonding to connect the ribbon wire at one end to the conductive layer or the first connecting member and at the other end to the busbar.

16. A manufacturing method of the power conversion apparatus according to claim 6, in which a lead frame is used as the second connecting member, and which comprises performing ultrasonic bonding to connect the lead frame at one end to the conductive layer or the first connecting member and at the other end to the busbar.
